(19) United States
(12) Patent Application Publication
(10) Pub. No.: US 2004/0128464 A1
(43) Pub. Date: Jul. 1, 2004

(54) Memory reclamation

(76) Inventors: Micheil J. Lee, Tempe, AZ (US); Richard P. MacKey, Phoenix, AZ (US); Joseph Murray, Scottsdale, AZ (US); Marc A. Goldschmidt, Scottsdale, AZ (US); Mark A. Schmisseur, Phoenix, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/331,843

(22) Filed: Dec. 30, 2002

(51) Int. Cl. G06F 12/00; G11C 11/34; G11C 16/06

(52) U.S. Cl. 711/171; 365/185.09; 365/185.11

(57) ABSTRACT

Embodiments of the present invention provide for configurable memory bus width and memory reclamation. In particular, the memory controller is configured to use a width of memory that is less than that fully available such that back-to-back writes can occur, as opposed to read-modify-writes. Unused regions of memory (defined by the total available memory width subtracted by the managed memory width) are partially or fully reclaimed, thus increasing the effective memory size available to the user. The configuration methods accommodate multiple interface bus widths while maintaining bandwidth not previously possible.

### BACKGROUND

1. Field

Conventionally, memory management implementing error correction code (ECC) is carried out to take full advantage of available memory capacity, where ECC is stored with data in memory. Since an ECC value is computed each time data is written to memory, a write to memory is done in bus width increments. To accomplish a write to memory of data less than the width of the memory bus (e.g., one byte or one word of a double word wide bus), a memory controller typically must read the data at the address in memory, modify the data read from memory with the new data being written, and write the modified data back to memory in a bus width increment. This is a time consuming process.

2. Relevant Art

A bus master on the bus may write to memory in less than bus width increments. If it does so when using ECC values to protect data in memory, the process is slow compared to writing bus width increments of data. More importantly, if a bus master writes a data increment less than a bus width to memory, a performance loss is incurred because of the read back that is necessary to complete the write and generate the proper ECC. Thus, this method of insuring data integrity is at the expense of performance when writing data to memory that is smaller than the memory bus width.

Referring to FIG. 1, a diagram of an embodiment 100 of a typical memory configuration is shown. In particular, up to n banks 102 of memory may exist, each having the same data bus width. The ECC is stored in parallel with each bank 104. This configuration becomes limited when considering data writes to memory banks 102 that are less than the full width of the data bus to the memory bank 102. In such event, the read-modify-write (RMW) is necessary to maintain FCC.

For example, referring to FIG. 2, a diagram of an embodiment 200 of a typical write transaction to memory 202 is shown. For these transactions, memory width is greater than the data width. In the case of the memory write to memory 202 from a bus 204 for a transaction that is not width aligned (specifically, the bus width is less than the memory data width), the memory controller 206 (MC) performs a RMW. The RMW is necessary because the memory controller 206 must first read the data from the memory 202 (including ECC), merge the data (write (n)) from the bus 204 with the memory data retrieved on the read, and finally write the new data (with new ECC) to memory 202. The memory controller 206 indicates to the bus 204 that it is busy when it is in the process of reading data from the memory 202, merging it together and then writing it to memory 202. In a typical implementation, for a 32-bit bus write to a 64-bit memory, the memory controller 206 must read back the full 64-bit data field (with ECC), merge in the 32-bits of data from the bus, and then write out a full 64-bit field of memory data including the ECC code that goes in parallel with the data. Since there are so many cycles in a RMW, there is an overall performance loss because the successive writes to the memory controller cannot be taken immediately. Bandwidth on the bus is degraded for the sake of using the entire memory data width.

### BRIEF DESCRIPTION OF THE DRAWINGS

FIG. 1 illustrates a diagram of a typical memory configuration.

FIG. 2 illustrates a diagram of a typical memory write transaction.

FIG. 3 illustrates a functional block diagram of an embodiment of an exemplary computer system embodying the present invention.

FIG. 4 illustrates a diagram of one embodiment of bus/memory data transactions with configurable memory data width.

FIG. 5 illustrates a diagram of one embodiment of a typical memory configuration.

FIG. 6 illustrates a diagram of an embodiment of a data write to memory using configurable memory bus.

FIG. 7 illustrates an embodiment of a data read to memory using configurable memory bus width.

FIG. 8 illustrates another embodiment of a data read to memory using configurable memory bus width.

FIG. 9 is a flow diagram of an embodiment of a routine configuring a memory bus width.

FIG. 10 is a flow diagram of an embodiment of a routine configuring a memory data width including calculating error correction data for the data.

FIG. 11 is a diagram of an embodiment of configurable memory data width in bank 0ₐ.

FIG. 12 is a diagram of an embodiment of reclaimed and configurable memory data width in both bank 0ₐ and bank 0_{b} where only data in bank 0ₐ is ECC protected.

FIG. 13 is a diagram of an embodiment of reclaimed and configurable memory data width in both bank 0ₐ and bank 0_{b} where data in both banks are ECC protected.

FIG. 14 is a flow diagram of an embodiment of a routine reclaiming and configuring a memory data width including calculating error correction data for the data.

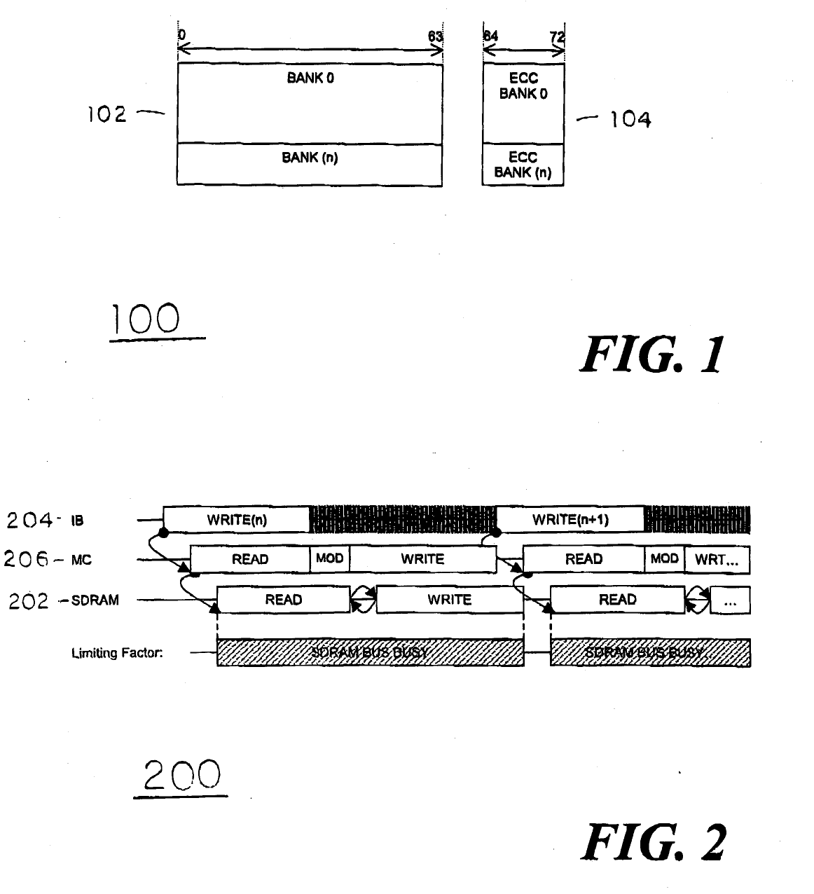

### DETAILED DESCRIPTION

Embodiments of the present invention provide for configurable memory bus width and memory reclamation. In particular, the memory controller is configured to use a width of memory that is less than that fully available such that back-to-back writes can occur, as opposed to read-modify-writes. Unused regions of memory (defined by the total available memory width subtracted by the managed memory width) are partially or fully reclaimed, thus increasing the effective memory size available to the user. The configuration methods accommodate multiple interface bus widths while maintaining bandwidth not previously possible.

In the detailed description, numerous specific details are set forth in order to provide a thorough understanding of the present invention. However, it will be understood by those skilled in the art that the present invention may be practiced without these specific details. In other instances, well-known methods, procedures, components and circuits have been described in detail so as not to obscure the present invention.

Some portions of the detailed description that follow are presented in terms of algorithms and symbolic representations of operations on data bits or binary signals within a computer. These algorithmic descriptions and representations are the means used by those skilled in the data processing arts to convey the substance of their work to others skilled in the art. An algorithm is here, and generally, considered to be a self-consistent sequence of steps leading to a desired result. The steps include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities. Unless specifically stated otherwise as apparent from the following discussions, it is appreciated that throughout the specification, discussions utilizing such terms as “processing” or “computing” or “calculating” or “determining” or the like, refer to the action and processes of a computer or computing system, or similar electronic computing device, that manipulate and transform data represented as physical (electronic) quantities within the computing system's registers and/or memories into other data similarly represented as physical quantities within the computing system's memories, registers or other such information storage, transmission or display devices.

Embodiments of the present invention may be implemented in hardware or software, or a combination of both. However, embodiments of the invention may be implemented as computer programs executing on programmable systems comprising at least one processor, a data storage system (including volatile and non-volatile memory and/or storage elements), at least one input device, and at least one output device. Program code may be applied to input data to perform the functions described herein and generate output information. The output information may be applied to one or more output devices, in known fashion. For purposes of this application, a processing system includes any system that has a processor, such as, for example, a digital signal processor (DSP), a micro-controller, an application specific integrated circuit (ASIC), or a microprocessor.

The programs may be implemented in a high level procedural or object oriented programming language to communicate with a processing system. The programs may also be implemented in assembly or machine language, if desired. In fact, the invention is not limited in scope to any particular programming language. In any case, the language may be a compiled or interpreted language.

The programs may be stored on a storage media or device (e.g., hard disk drive, floppy disk drive, read only memory (ROM), CD-ROM device, flash memory device, digital versatile disk (DVD), or other storage device) readable by a general or special purpose programmable processing system, for configuring and operating the processing system when the storage media or device is read by the processing system to perform the procedures described herein. Embodiments of the invention may also be considered to be implemented as a machine-readable storage medium, configured for use with a processing system, where the storage medium so configured causes the processing system to operate in a specific and predefined manner to perform the functions described herein.

For illustrative purposes, embodiments of the present invention are discussed utilizing a bus, memory controller and memory. Embodiments of the present invention are not limited to such a configuration though.

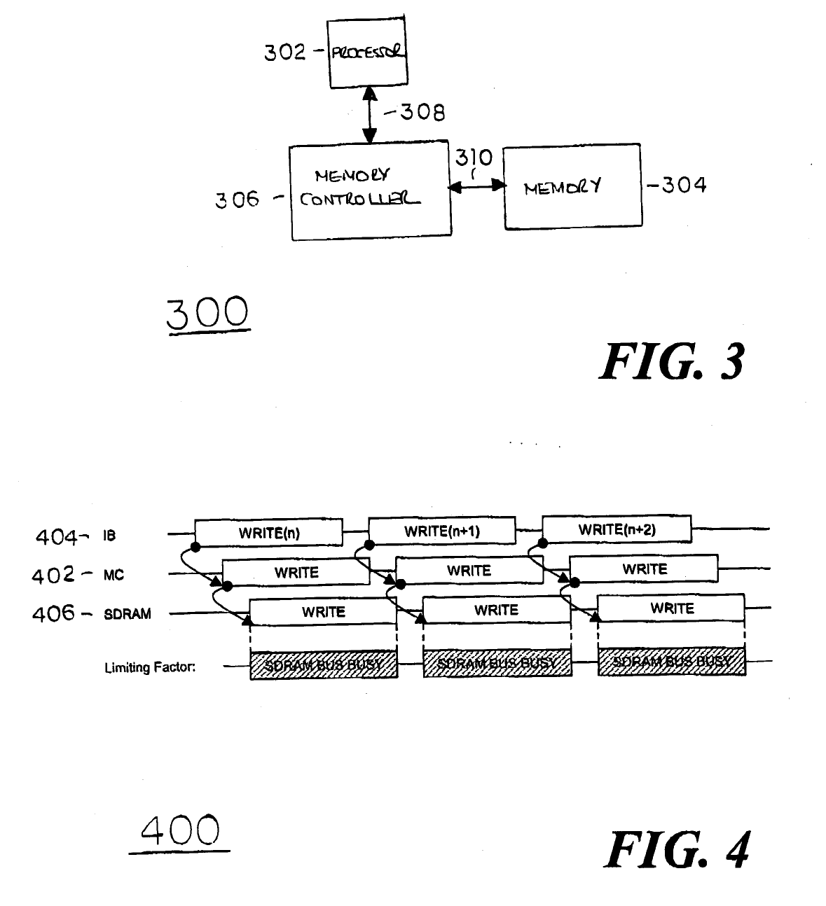

FIG. 3 illustrates a functional block diagram of an embodiment 300 of an exemplary computer system embodying the present invention. Computer system includes processor 302, memory 304 and memory controller 306. Memory 304 is a memory in which application programs are stored and from which processor 302 primarily executes. One skilled in the art will recognize that memory can be comprised of other types of memory and any references to a particular type of memory is for illustrative purposes only. For example, memory 304 can be comprised of SDRAM (Synchronous DRAM) or RDRAM (RAMBUS DRAM), DRAM, FLASH or DDR (Double Data Rate synchronous DRAM). Embodiments of the present invention can be implemented in a variety of systems (SDRAM, FLASH, DRAM, DDR, etc) and is backward compatible with current memory management techniques. For exemplary purposes, data transfers from a bus to a memory will be used to illustrate embodiments of the present invention. One skilled in the art will recognize that embodiments of the invention are applicable to other bus to memory configurations.

As used herein, a “memory request” is a transfer of command and address between an initiator and memory 304. A “read memory request” is a transfer of data from memory 304 to the initiator. For example, processor 302 may initiate a read memory request to transfer data from memory 304 to processor 302. A “write memory request” is a transfer of data from the initiator to memory 304. For example, processor 302 may initiate a write memory request to transfer data from processor 302 to memory 304. Control information (including, e.g. the priority level and the read/write nature of the memory request) may be conveyed concurrent with the memory request or using a predefined protocol with respect to conveyance of the address. Processor 302 is coupled to memory controller 306 by bus 308. Memory controller 306 is in turn coupled to memory 304 by memory bus 310.

The configurations shown herein are examples of memory subsystem configurations that can be employed in practicing the present invention. For example, the number of memory banks, data widths and FCC banks widths that can be employed in practicing the present invention may all vary from what is shown.

Configurable Memory Bus Width

Memory configured and managed by a memory controller typically takes full advantage of available memory capacity. While this represents effective usage of memory space, it can be at the expense of effective bandwidth when implementing ECC. This problem is exemplified when performing writes from a transfer device, such as an arbitrary bus, to a memory where the transfer device data width (defined as bits of data to be transferred per address cycle) does not match the memory data width. The difference in data width between the transfer device and memory inherently adds latency to data transfers managed by memory controllers, including those that implement ECC. This latency, expressed as bus cycles to memory cycles in the case of an arbitrary bus, can be overcome if the configuration of the memory width is no longer considered as a constant, but a variable that can be adjusted for different regions of memory. For illustrative purposes, embodiments of the present invention are discussed and shown with an internal bus as the transfer device although one skilled in the art will recognize that the transfer device is not limited to such. Rather the present invention may be adopted to configuring the data width any time there is a difference between a device data width and the memory data width.

Referring to FIG. 4, a diagram of one embodiment 400 of bus/memory data transactions with configurable memory data width is illustrated. In particular, the memory controller 402 is configured to use a width of memory that is less than that fully available such that back-to-back writes, rather than read-modify-writes, can occur. The bandwidth of data transfers to/from the memory 406 (for example, SDRAM) originating from a device 404 (for example, bus) of a differing data width is increased. Memory controllers 402 that interface between differing data widths will notice an increase in performance. For example, once the data width of the memory 406 is configured to match the data width of the device 404, bandwidth is increased.

In a typical implementation, with the optimization in place, data (write(n)) is taken directly from the bus 404 through the memory controller 402 and posted to the SDRAM 406 without having to do a read-modify-write cycle. Since the read and modify cycles are eliminated, writes flow directly through the bus through the memory controller 402 to the SDRAM 406. SDRAM bus is busy only for the duration of the write cycle.

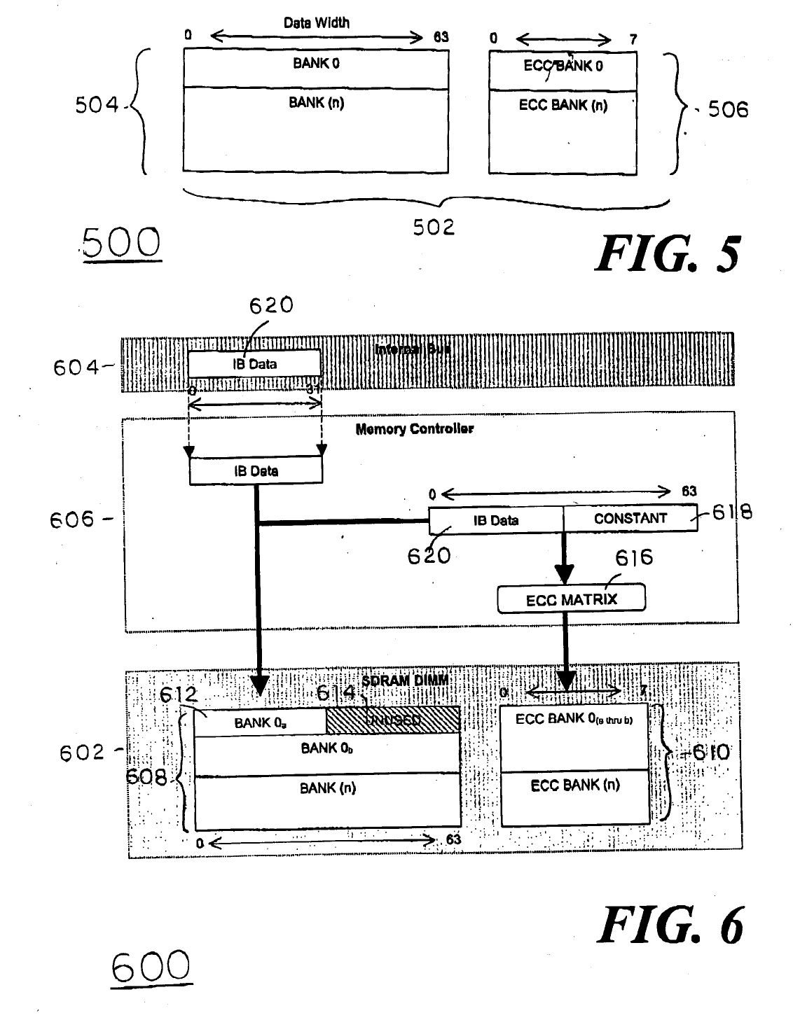

Referring to FIG. 5, a diagram of one embodiment 500 of a typical memory 502 configuration having n banks 504 and n corresponding ECC banks 506 is shown. As is typical of a 64-bit ECC protected memory 502, there is no division of memory within any of the banks 502. Each bank 502 has a set data width, such as 64-bits. An ECC value is computed for the entire bus width of data. For example, an ECC value for a 64-bit bus width increment of data stored in memory 502 may be eight bits. Such a value allows detection of all one and two bit errors, the detection of errors in four consecutive bits in certain types of memory, and the correction of all single bit errors.

Referring to FIG. 6, a diagram of an embodiment 600 of a data write to memory 602 using a configurable memory bus width is shown. In particular, the configuration shown includes a 32-bit bus 604, memory controller 606 and 64-bit memory 602. Memory 602 may be SDRAM memory and includes a plurality of banks 608 for data storage and a plurality of banks 610 for error correction storage.

The memory controller 606 maps the IB data to a portion (designated bank 0ₐ) 612 of the memory bank 608 to match the data width 620 of the bus 604 to that of the memory 602/608. The remainder 614 of the memory bank 608 remains unused. A portion of memory 602/608, such as bank 0a 612, is configured to suit the specific application. In this case, a 64-bit memory is configured to appear as a 32-bit memory. The size of bank 0ₐ 612 is defined by the user, and can be set to 0 if the user does not want to configure the memory bus width. This allows backward compatibility with existing software applications. Further, by allowing the user to define the size of bank 0a 612, the user can fully manage the performance gain of the configuration versus the capacity loss.

The ECC for all regions of bank 0 are calculated similarly using the existing ECC matrix 616. The ECC matrix 616 is an arbitrary algorithm appropriate for the particular application. In particular, ECC is generated as a part of an error correction process and is used to detect storage errors in memory arrays and correct some of those errors. An error correction process uses a math function to compute during storage an error correction code (referred to herein as a check value or ECC value) that is unique to the data stored. A check value is stored in memory 610 (ECC banks 0 thru n) in association with the data. When the data is read back, a determination is made whether the data read would produce the check value stored with the data. If the data would not produce the check value stored, some change has occurred in the data or the check value since they were stored. If the value has changed, then the data and the check value read from memory are sometimes used to accomplish the correction of the data depending on the type of error. The data values from the memory controller 606 are provided to an ECC matrix 616.

When writing to bank 0a 612, the memory controller 606 implements a constant 618 in the unused portion of the data field to calculate the ECC. For example, 8-bits of ECC is calculated by holding constant the upper portion of the remaining 32-bits of the 64-bit memory controller bus when applying the ECC matrix 616. The constant 618 is an arbitrary value selected based on the parameters of the ECC matrix calculation. This maintains the functionality of ECC when reading data back from memory 602, and forgoes the implementation of an additional ECC matrix.

The bus data width is configured to be the same as that of the memory 602. The memory controller 606 is thus free to burst data to each successive address location in the memory region defined by bank 0ₐ 612. The read-modify-write can be omitted, and the bandwidth is maximized to the memory 602. Reading data back from bank 0ₐ 612 is simplified by configuring the memory data width. Although current memory controllers can achieve the same bandwidth on reads, they do so at the expense of read data queues or an memory throttling mechanism.

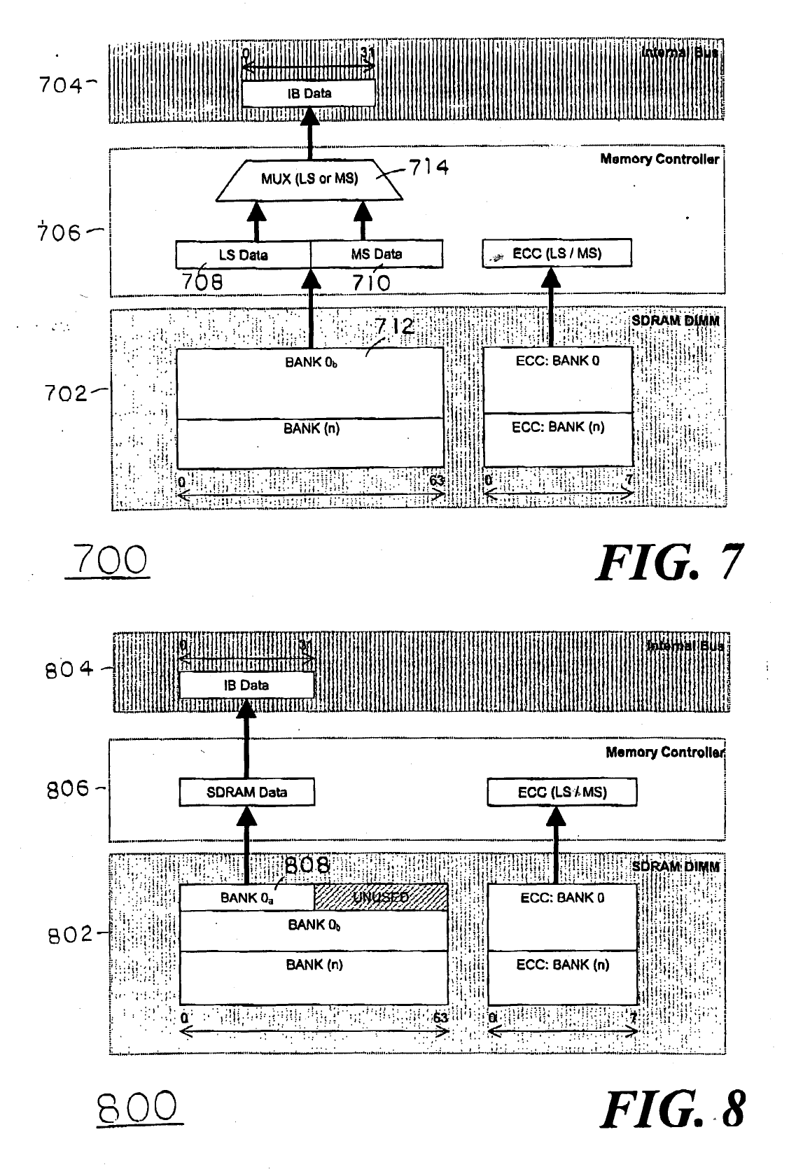

Referring to FIG. 7, an embodiment 700 of a data read to memory 702 using configurable memory bus width is illustrated. In particular, a 64-bit memory 702 and 32-bit bus 704 which implements a throttle mechanism to slow data flow from the memory 702 to the bus 704 is shown. There are two words of data (LS data 708 and MS data 710) stacked in each address location of memory 702, which causes the memory controller 706 to read data back twice as fast as the bus 704 can accept. In particular, LS data 708 represents the least significant data and MS data 710 represents the most significant data in the 64-bit data field.

The memory controller 706 unstacks the 64-bit data into two 32-bit data words 708 and 710 that can be sent back to the bus 704. In particular, unstacked data from a 32-bit memory system is illustrated. In executing 32-bit reads, data is stacked to a bus 704 that is 32-bits wide. For example, if data is read from a bank 712 that is 64-bits wide, such as bank 0_{b}, 64-bits of data cannot be presented to the bus 704 at a time because the bus 704 is only 32-bits wide. A multiplexor 714 selects between the LS data 708 and MS data 710.

FIG. 8 illustrates an embodiment 800 of a data read from memory 802 using configurable memory bus width that discards the throttling mechanism and data queue that was previously necessary in memory controllers. The memory controller 806 configures the data width between the memory 802 and bus 804, increasing the bandwidth of bus writes (read from memory) as well as simplifying the logic controlling reads. The data width from bank 0ₐ 808 matches the data width of the bus 804, thus reducing the need for additional hardware, including a multiplexor.

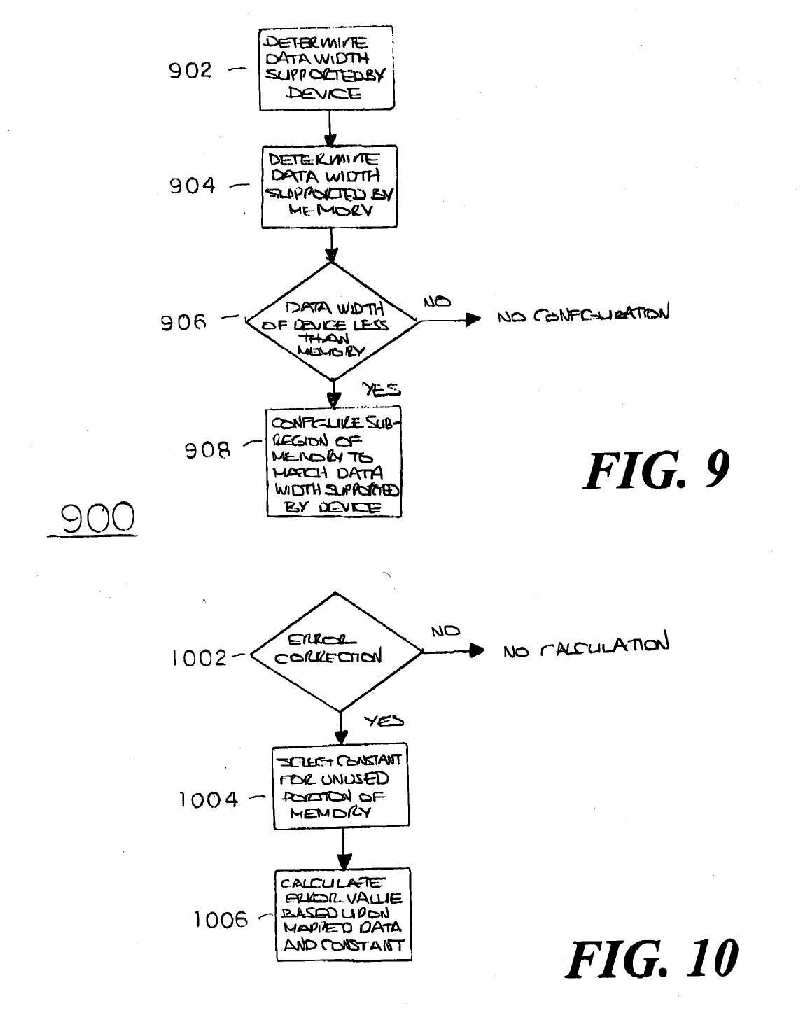

FIG. 9 is a flow diagram of an embodiment 900 of a routine configuring a memory data width.

In step 902, the data width supported by a device is determined.

In step 904, the data width supported by a region of memory is determined.

In step 906, it is determined whether the data width supported by the device differs from the data width supported by the region of memory.

In step 908, a first sub-region of memory is configured to have a data width less than that fully available if the data width supported by the device is less than from the data width supported by the region of memory. In particular, the first sub-region of memory is configured to have a data width that matches the data width supported by the device.

FIG. 10 is a flow diagram of an embodiment of a routine configuring a memory data width including calculating error correction data for the data.

In step 1002, it is determined whether error correction data is desired.

In step 1004, if error correction data is desired, a constant value for error correction is associated with the unused region of memory.

In step 1006, calculating error correction value based upon the data mapped in the sub-region of the memory and the constant value in the unused region of the memory.

In particular, in a system where the memory controller implements data width management, there is some unused region of memory defined by the total available memory width subtracted by the managed memory width, as configured by the user. Embodiments of the present invention reclaim used memory, thus increasing the effective memory size available to the user. The configuration methods accommadate multiple interface bus widths while maintaining bandwidth not previously possible.

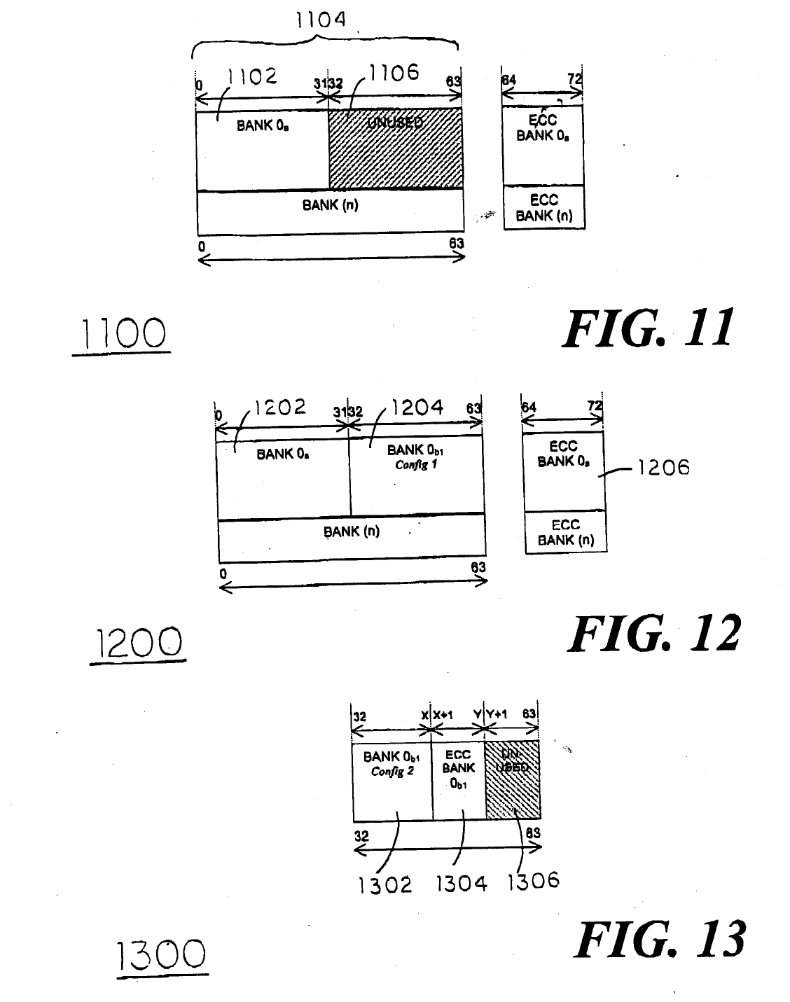

FIG. 11 is a diagram of an embodiment 1100 of configurable memory data width in bank 0ₐ. Configuring the target memory such that it has a data width the same as that of the inbound transfer compensates for any performance decrease caused by the RMW. As noted above, bank 0ₐ 1102 could be configured as a 32-bit wide data field, creating a new memory region (i.e., bank 0ₐ) within the memory 1104. This results in unused memory space 1106.

FIG. 12 is a diagram of an embodiment 1200 of reclaimed and configurable memory data width in both bank 0ₐ 1202 and bank 0_{b} 1204 where only data in bank 0ₐ is ECC protected. To reclaim unused memory such as the upper half of bank 0 1106 shown in FIG. 11, the memory controller maps the unused portion as another parallel memory region. Thus, two memory regions are now defined within bank 0: bank 0ₐ 1202 and bank 0_{b} 1204. Bank 0ₐ 1202 is utilized in exactly the same manner as it was before: data is stored in bank 0ₐ 1202, while the ECC for that transfer is stored in parallel to the data in the ECC region (for example, ECC bank 0ₐ1206, bits 64 to 74). The data width of bank 0_{b} 1204 is arbitrarily chosen to be 32-bits but can be configured as a width less than or equal to that available.

Unused memory can then be reclaimed with or without ECC. One skilled in the art will recognize that the choice to implement ECC in a memory system is based upon the dependability and quality of memory. Systems implement ECC typically implement ECC for the reclaimed memory region. If the reclaimed memory region 0_{b} 1204 does not use ECC, then the reclaimed memory region exists as the data width from the end of bank 0ₐ 1202 to the beginning of the ECC region for bank 0ₐ1204. ECC for bank 0ₐ 1202 is stored in the ECC bank 0ₐ 1206. Data in bank 0_{b} 1204 is not ECC protected.

FIG. 13 is a diagram of an embodiment 1300 of reclaimed and configurable memory data width in both bank 0ₐ and bank 0_{b} where data in both banks are ECC protected. If it is necessary to protect the reclaimed memory by implementing ECC, an area aside from the newly defined memory region is defined to store the ECC. An example of this, shown FIG. 13, is a memory region 1302 whose functional memory width is defined from bit 32 to bit X. This memory width is controlled by the user, but is bound by ECC algorithms that dictate a necessary number of bits to generate ECC for the number of data bits. The configuration for bank 0 1302 implements an ECC scheme for data [32:x]. ECC for bank 0_{b} is stored in the ECC bank 0_{b} [x+1:y] 1304. It is still possible to have unused memory, for example, unused region [y+1:63] 1306. However, the memory loss is significantly less and other performance gains are achieved.

One skilled in the art will recognize that the memory region can be divided into more than one region. How many regions are dependent upon the number of different bus widths the memory region must serve. Thus, it is possible to write data from several different bus widths while maintaining the ability to burst data for each configuration, and not lose bandwidth to RMWs.

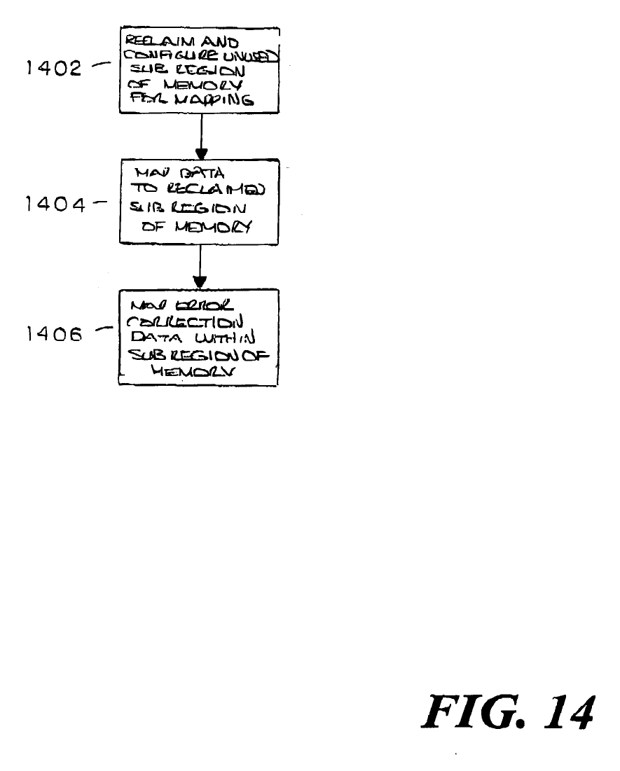

FIG. 14 is a flow diagram of an embodiment of a routine reclaiming and configuring a memory data width including calculating error correction data for the data.

In step 1402, an unused sub-region of memory is reclaimed and configured as a second sub-region of memory.

In step 1404, data is mapped to the reclaimed sub-region of memory.

In step 1406, error correction data, if any, for data mapped in the second sub-region is stored within the second sub-region of data.

The above description of illustrated embodiments of the invention is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize. These modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

What is claimed is:

1. A method for providing a configurable memory data width, comprising:
determining a data width supported by a device;
determining a data width supported by a region of memory;
mapping data from the device to a first sub-region of the memory;
reclaiming an unused sub-region of memory and configuring it as a second sub-region of memory; and
mapping the second sub-region of memory as another parallel memory region.

2. The method claimed in claim 2, further comprising:
storing error correction data for data mapped in the first sub-region in parallel to the data in an error correction region of memory.

3. The method claimed in claim 2, further comprising:
storing error correction data for data mapped in the second sub-region within the second sub-region of data.

4. The method claimed in claim 3, wherein the memory comprises a memory having a plurality of banks.

5. The method claimed in claim 4, wherein the first sub-region comprises a region of a bank of memory.

6. The method claimed in claim 1, wherein the memory comprises a 64-bit SDRAM and the bus comprises a 32-bit internal bus.

7. The method claimed in claim 1, further comprising:
configuring a first sub-region of memory having a data width less than that fully available when the data width supported by the device differs from the data width supported by the region of memory.

8. A machine readable medium having stored therein a plurality of machine readable instructions executable by a processor to provide a configurable memory data width, comprising:
instructions to determine a data width supported by a device;
instructions to determine a data width supported by a region of memory;
instructions to map data from the device to a first sub-region of memory;
instructions to reclaim an unused sub-region of memory and configuring it as a second sub-region of memory; and
instructions to map the second sub-region of memory as another parallel memory region.

9. The machine readable medium claimed in claim 8, further comprising:
instructions to store error correction data for data mapped in the first sub-region in parallel to the data in an error correction region of memory.

10. The machine readable medium claimed in claim 9, further comprising:
instructions to store error correction data for data mapped in the second sub-region within the second sub-region of data.

11. The machine readable medium claimed in claim 10, wherein the memory comprises a memory having a plurality of banks.

12. The machine readable medium claimed in claim 11, wherein the first sub-region comprises a region of a bank of memory.

13. The machine readable medium claimed in claim 12, wherein the memory comprises a 64-bit SDRAM and the bus comprises a 32-bit internal bus.

14. The machine readable medium claimed in claim 8, further comprising:
instructions to configure a first sub-region of memory having a data width less than that fully available when the data width supported by the device differs from the data width supported by the region of memory.

15. An apparatus for providing a configurable memory data width, comprising:
a device supporting a first data width;
a memory supporting a second data width; and
a controller in communication with the device and memory, wherein the controller maps data from the device to a first sub-region of the memory, reclaims an unused sub-region of memory, configures the unused sub-region of memory as a second sub-region of memory, and maps the second sub-region of memory as another memory region.

16. The apparatus claimed in claim 15, wherein the controller stores error correction data for data mapped in the first sub-region in parallel to the data in an error correction region of memory.

17. The apparatus claimed in claim 16, wherein the controller stores error correction data for data mapped in the second sub-region within the second sub-region of data.

18. The apparatus claimed in claim 17, wherein the memory comprises a memory having a plurality of banks.

19. The apparatus claimed in claim 18, wherein the first sub-region comprises a region of a bank of memory.

20. The apparatus claimed in claim 19, wherein the memory comprises a 64-bit SDRAM and the bus comprises a 32-bit internal bus.

21. The apparatus claimed in claim 25, wherein the controller configures a first sub-region of memory having a data width less than that fully available when the data width supported by the device differs from the data width supported by the region of memory, and maps data from the device to the configured first sub-region of the memory.
